(19) United States
(12) Patent Application Publication
(10) Pub. No.: US 2010/0163990 A1
(43) Pub. Date: Jul. 1, 2010

(54) Lateral Double Diffused Metal Oxide Semiconductor Device

(76) Inventor: Choul Joo KO, Seongnam-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/646,218

(22) Filed: Dec. 23, 2009

(30) Foreign Application Priority Data
Dec. 31, 2008 (KR) 10-2008-0138251

(51) Int. Cl. H01L 29/78; H01L 21/336

(52) U.S. Cl. 257/343; 438/286; 257/E21.417; 257/E29.261

(57) ABSTRACT

Disclosed is a lateral double diffused metal oxide semiconductor (LDMOS) device and methods of making the same. The LDMOS device may include a semiconductor substrate comprising a buried region and a first well region, a gate on the semiconductor substrate, a body region in the first well region and a source region in the body region on one side of the gate, a drift region and a drain region in the drift region on an opposite side of the gate relative to the body region, a second well region, a first deep sink region and a third well region in the first well region, and a second deep sink region in the first well region.

### CROSS-REFERENCE TO RELATED APPLICATIONS

This application claims the benefit of Korean Patent Application No. 10-2008-0138251, filed on Dec. 31, 2008, which is hereby incorporated by reference as if fully set forth herein.

### BACKGROUND OF THE INVENTION

1. Field of the Invention

The present invention relates to semiconductor technology. More specifically, the present invention relates to a lateral double diffused metal oxide semiconductor (LDMOS) device.

2. Discussion of the Related Art

The improvement in integration level of semiconductor devices, and thus development in fabrication design techniques thereof, has brought about a number of efforts to realize a semiconductor system on a single chip. Such a single chip system has been developed based on technology to integrate controllers, memories and circuits operating at low voltages into a single chip.

However, to realize low weight and miniaturization of a semiconductor system, it is necessary to integrate a circuit part to control power of the system, e.g., input and output terminals and main functional circuits into a single chip. However, input and output terminals cannot be realized as a low-voltage CMOS circuit when high voltages are applied thereto. Accordingly, such terminals are generally realized as high-voltage power transistors.

To reduce the size and weight of systems, input/output terminals of a power source and a controller should be integrated into a single chip. A technology to realize this integration is a power IC, wherein a high-voltage transistor circuit and a low-voltage CMOS transistor circuit are integrated into a single chip.

Such an integrated power IC technology can include a lateral DMOS (LDMOS) device, an improvement of a vertical DMOS (VDMOS) device (a related art discrete power transistor). In an LDMOS device, the drain is laterally arranged to allow current to laterally flow, and a drift region is interposed between the channel and the drain to assure high breakdown voltage.

An LDMOS device according to the related art will be described with reference to the appended drawings.

FIG. 1 is a cross-sectional view illustrating the structure of the LDMOS device according to the related art.

Referring to FIG. 1, an n-type buried layer (NBL) 90 and a high voltage n-well (HV NWELL) 80 are formed in a semiconductor substrate (P-SUB) wherein active regions are defined by a patterned device-isolation film 60. In particular, the HV NWELL 80 is formed above NBL 90.

A gate pattern 50 is formed on the semiconductor substrate such that it overlaps the device-isolation film 60. A p-body 30 is formed in the HV NWELL 80 on one side of the gate pattern 50 and a source region 40 is formed in the p-body 30. In addition, a low voltage N-well (LV NWELL) 11 is formed in the HV NWELL 80 on the other side of the gate pattern 50 and a drain region 10 is formed in the LV NWELL 11.

The LDMOS device of FIG. 1 utilizes a PWELL 20, which is separated from the drain region 10 by the device-isolation film 60. An n-type sink 70 is formed outward from the PWELL 20 as a guardring.

In the case where the drain region 10 and the PWELL are electrically connected, a higher voltage may be applied to the source region 40 and the p-body 30 in the LDMOS device, as compared to the case where the drain region and the PWELL 20 are not electrically connected, when current flows in a reverse direction (e.g., from an inductor in a bridge circuit). The operation of the LDMOS device of FIG. 1 will now be described with reference to FIG. 2.

FIG. 2 is a cross-sectional view illustrating the operation of the LDMOS device of FIG. 1.

In FIG. 2, when a parasitic bipolar transistor (PNP1) 91 operates, hole current is discharged to the semiconductor substrate (P-SUB). However, hole current also flows to the PWELL 20 via the PNP2 81. Consequently, the current gain (Hfe) of the parasitic PNP1 91 may be reduced. This prevents hole current from being transmitted to the semiconductor substrate when current flows in reverse, e.g., due to an inductor.

As shown in FIG. 3A, this behavior is demonstrated by comparing the current gain (Hfe) B of the parasitic PNP1 91 in the case where the PWELL 20 as the guardring is present, with the current gain (Hfe) A of the parasitic PNP1 91 in the case where the PWELL 20 of the guardring is absent. In the case where the PWELL 20 of the guardring is present, the current gain (Hfe) B of the parasitic PNP1 91 is considerably reduced. However, this case has a disadvantage, as shown in FIG. 3B.

FIG. 3B is a graph showing variations in on-state break down voltage (Bvii) of the LDMOS transistor depending on the presence/absence of a PWELL as a guardring in the LDMOS of FIG. 1.

When the PWELL 20 of the guardring is absent in the LDMOS, the on-state break down voltage of the LDMOS transistor (Bvii) is 102 volts (A′). On the other hand, when the PWELL 20 of the guardring is present in the LDMOS, on-state break down voltage (Bvii) of the LDMOS transistor is 73 volts (B′). Thus, the current gain (Hfe) of parasitic PNP1 can be reduced, and current discharged to the semiconductor substrate (a noise-causing factor) can thus be decreased by inclusion of PWELL 20 as a guardring in the LDMOS of FIG. 1. However, in this case, the problem where on-state break down voltage (Bvii) of the LDMOS transistor is decreased occurs, which causes deterioration in the safe operating area (SOA) properties of the LDMOS transistor.

FIG. 4 is a cross-sectional view illustrating the operation of the LDMOS of FIG. 1 when a positive (+) voltage (V_{DD}) and a positive (+) voltage (V_{G}) are applied to a drain region and a gate region, respectively.

Electrons mostly enter the LV NWELL 11. The resistance of the N-WELL 11 corresponding to the drift region (e.g., represented by resistor R2 12) may undergo a voltage drop. Since the PWELL 20 is electrically connected with the drain region 10, the voltage drop may thus occur in the PWELL 20 as well as in the drift region.

That is, hole current flows from the PWELL 20 toward the source region 40 and the p-body 30, thus promoting operation of the parasitic PNP1 91. As a result, the on-state break down voltage (Bvii) of the LDMOS may deteriorate when the PWELL 20 is used as a guardring.

### SUMMARY OF THE INVENTION

Accordingly, the present invention is directed to a lateral double diffused metal oxide semiconductor (LDMOS) device that substantially obviates one or more problems due to limitations and disadvantages of the related art.

Objects of the present invention include providing a lateral double diffused metal oxide semiconductor (LDMOS) device and methods for making the same, to improve the safe operating area (SOA) properties and guardring performance of the LDMOS device, without causing deterioration in on-state break down voltage (Bvii).

To achieve these objects and other advantages in accordance with the purpose(s) of the invention as embodied and broadly described herein, provided is a lateral double diffused metal oxide semiconductor (LDMOS) device, including: a semiconductor substrate including a buried region and a first well region; a gate on the semiconductor substrate; a body region in the first well region and a source region in the body region on one side of the gate; a drift region and a drain region in the drift region on an opposite side of the gate relative to the body region; a second well region, a deep first sink region and a third well region in the first well region; and a second deep sink region in the first well region.

In another aspect, the present invention provides a method of making a lateral double diffused metal oxide semiconductor (LDMOS) device including forming a buried region and a first well region in a semiconductor substrate; forming first and second deep sink regions in the first well region, where the first deep sink region is in electrical contact with the buried region; forming a device isolation layer on and/or in the semiconductor substrate; forming a gate on the semiconductor substrate and at least part of the device isolation layer; forming a low voltage well in the first well region on one side of the gate; forming a body region, a second well region and a third well region in the first well region, where the body region is on an opposite side of the gate relative to the low voltage well; forming a source region in the body region, and first and second contact regions in the second and third well regions, respectively; and forming a drain region in the low voltage well region and a third contact region in the first deep sink region.

The drift region including the drain region, the second well region, the first deep sink region, the third well region, and the second deep sink region may be isolated from one another by one or more device isolation films.

The drain region, the second well region, the first deep sink region, and the third well region may be electrically connected.

The first well region may be a high voltage n-well (HV n-type well). The drift region may comprise a low voltage n-well (LV n-type well). The second and third well regions may be p-type wells. The first and second deep sink regions may be heavily doped n-type sink regions (n⁺-sink).

It is to be understood that both the foregoing general description and the following detailed description of embodiments of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and along with the description serve to explain the principles of the invention. In the drawings:

FIG. 1 is a cross-sectional view of the structure of an LDMOS device according to the related art;

FIG. 2 is a cross-sectional view illustrating operation(s) of an LDMOS device of FIG. 1;

FIG. 3A is a graph showing parasitic PNP current gain (Hfe) depending on the presence/absence of a PWELL guardring in the LDMOS of FIG. 1;

FIG. 3B is a graph showing variations in on-state break down voltage (Bvii) depending on the presence/absence of the PWELL guardring in the LDMOS of FIG. 1;

FIG. 4 is a cross-sectional view illustrating an example wherein the LDMOS of FIG. 1 operates when a positive (+) voltage (V_{DD}) and a positive (+) voltage (V_{G}) are applied to a drain region and a gate region, respectively;

FIG. 5 is a cross-sectional view of an exemplary structure of an LDMOS device according to embodiments the present invention; and

FIG. 6 is a cross-sectional view illustrating the operation(s) of the LDMOS device of FIG. 5.

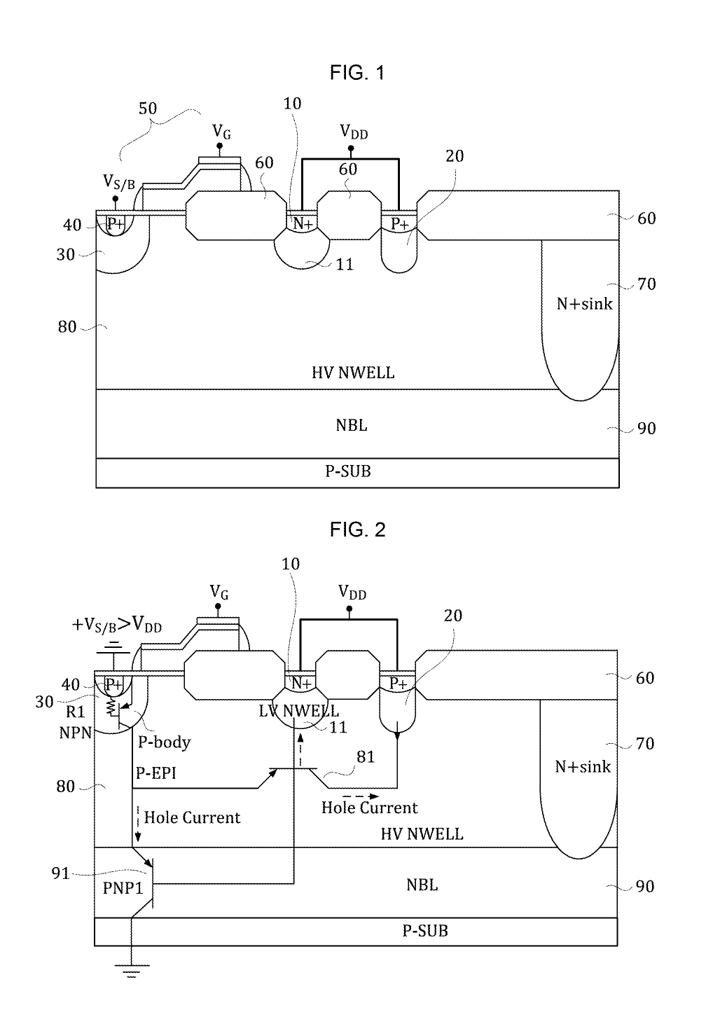

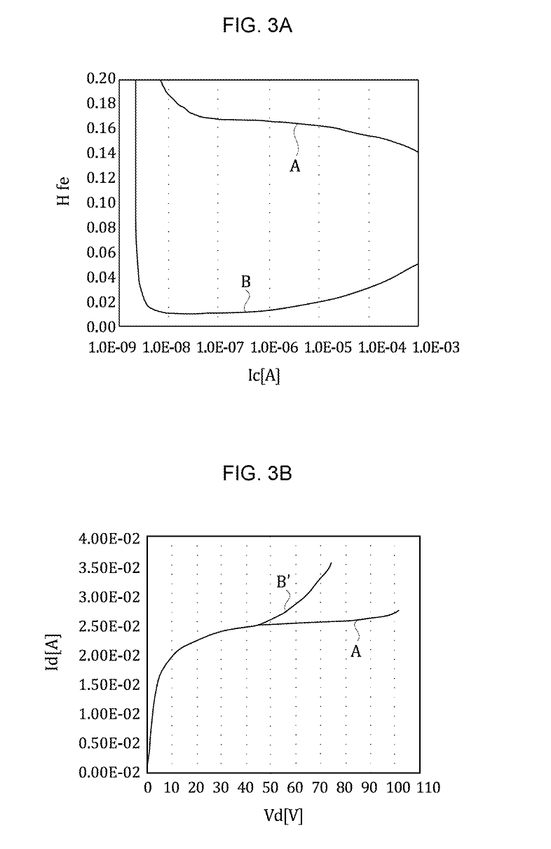

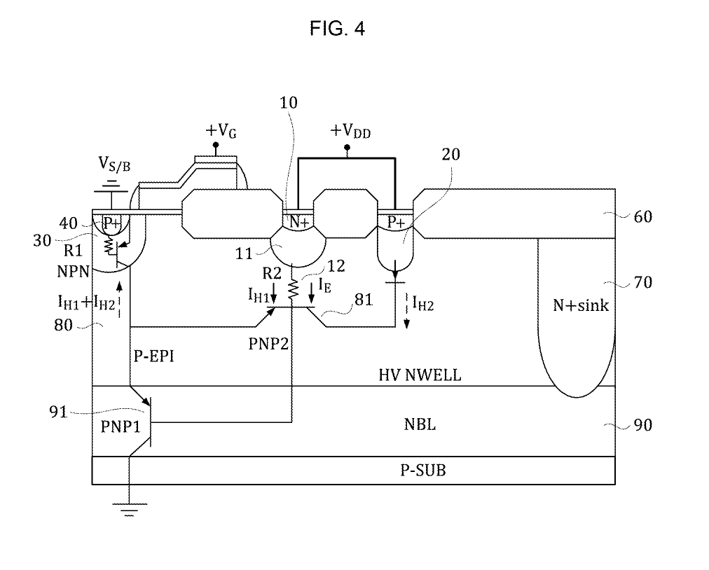

### DETAILED DESCRIPTION

The above and other objects, features and other advantages of the present invention will be more clearly understood from the following detailed description taken in conjunction with the accompanying drawings.

Although the configurations and functions of embodiments of the present invention are illustrated at least in part in the accompanying drawings, in conjunction with at least one embodiment, and described with reference to the accompanying drawings, the technical idea of the present invention and the important configurations and functions thereof are not limited thereto.

Hereinafter, a lateral double diffused metal oxide semiconductor (LDMOS) device according to embodiments of the present invention will be described with reference to the appended drawings.

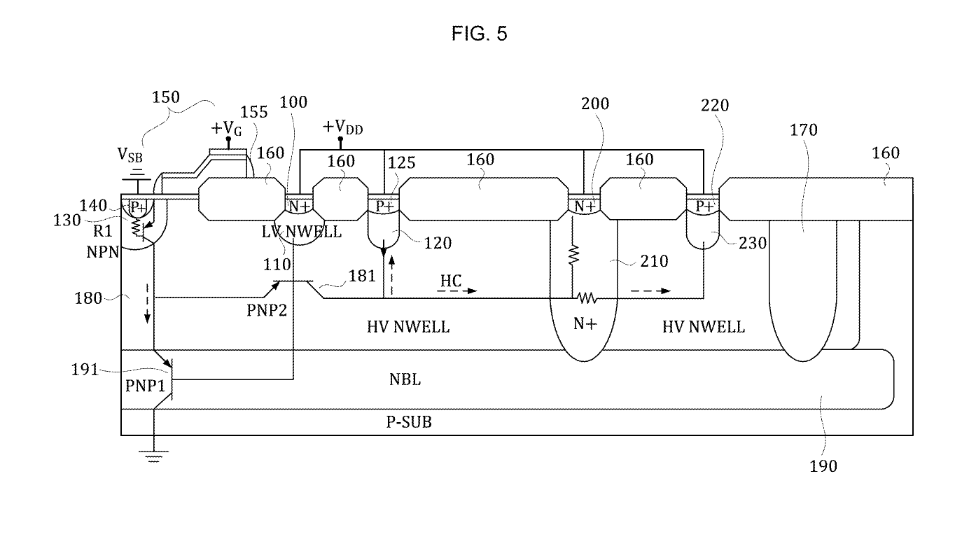

FIG. 5 is a cross-sectional view of an exemplary structure of an LDMOS device according to embodiments of the present invention.

Referring to FIG. 5, a semiconductor substrate (P-SUB), wherein one or more active regions are defined by a device-isolation film 160, comprises a buried region 190 and a first well region 180. The buried region may be an n-buried layer (NBL), and the first well region may be a high voltage n-well (HV NWELL). As a result, the HV NWELL 180 is arranged on or above the NBL 190.

A gate pattern 150 is formed (generally by CVD of silicon onto a thin thermal oxide film, followed by photolithographic patterning and etching) on the semiconductor substrate such that it overlaps part of the device isolation film 160.

A source region 140 and a body region 130 including the source region 140 are provided in the HV NWELL 180 on one side of the gate pattern 150. The body region 130 may be a p-type body.

A drain region 100 and a drift region including the drain region 100 are provided in the HV NWELL 180 on an opposite side of gate pattern 150 relative to the body region 130. The drift region may include low voltage n-well (LV NWELL) 110.

A second well region that may be configured to function as a guardring, a first deep sink region and a third well region are provided in this order in an outer direction from the LV NWELL 110 including the drain region 100. The second well region 120 may be a PWELL, and may include a p+ contact region 125. The first deep sink region 210 may be a deep n-type sink region (N+ sink), and the third well region 230 may be a second PWELL. The deep n-type sink region (N+ sink) 210 is generally provided with an N+ (e.g., heavily doped n-type) contact region 200, and the PWELL 230 is generally provided with a p+ (e.g., heavily doped p-type) contact region 220.

A second deep sink region 170 for connection is provided peripherally to the PWELL 230 corresponding to the third well region. The deep second sink region may be an n-type sink (N+ sink) region.

Certain structures and or regions of the present LDMOS may be formed at the same time or during the same processing step(s). For example deep sink regions 210 and 170 may be formed in one process step by, e.g., implanting n-type impurities in the first well region through a first mask. Similarly, body region 130, second well region 120 and third well region 230 may be formed in one process step by implanting, e.g., p-type impurities in the first well region through a second mask. In addition, source region 140, and p+ contact regions 125 and 220 may be formed in one process step by injecting, e.g., p-type impurities in the second and third well regions through a third mask. Drain region 100 and n+ contact region 200 may also be formed in one process step by, e.g., implanting n-type impurities through a fourth mask. Each of the first through fourth masks may comprise, e.g., a patterned photoresist. In addition, the implantation to form the body region 130 may be performed using the gate 150 (and, optionally, the sidewall spacer 155 adjacent thereto) as a mask.

The LDMOS structure according to various embodiments the present invention will be described in detail.

On one side of the gate pattern 150, the LDMOS device includes a p-body 130 and a source region 140 therein.

In addition, on an opposite side of the gate pattern 150, the LDMOS device includes drain region 100 in the LV NWELL 110, the PWELL 120 of the guardring, the deep n-type sink region (N+ sink) 210 and the PWELL 230 from the gate pattern 150 to the n-type sink (N+ Sink) region 170 for connection arranged in this order. In particular, the drain region 100 present in the LV NWELL 110, the PWELL 120 of the guardring, the deep n-type sink region (N+sink) 210 and the PWELL 230 are isolated from one another by the device isolation film 160.

In addition, the drain region 100, the PWELL 120, the deep n-type sink region (N+ sink) 210 and the PWELL 230 are electrically connected with the LV NWELL 110. The deep n-type sink region (N+ sink) 210 may be formed up to a depth of the n-buried layer (NBL) 190.

As shown in FIG. 5, in the LDMOS structure, when the parasitic PNP1 191 operates, a great amount of hole current flows to the right. That is, as shown in FIG. 5, the hole current (HC) flows to the PWELL 120 as a guardring and flows to the additional deep n-type sink region (N+sink) 210 and the PWELL 230. As a result, injection of the hole current of parasitic PNP into the semiconductor substrate can be substantially prevented.

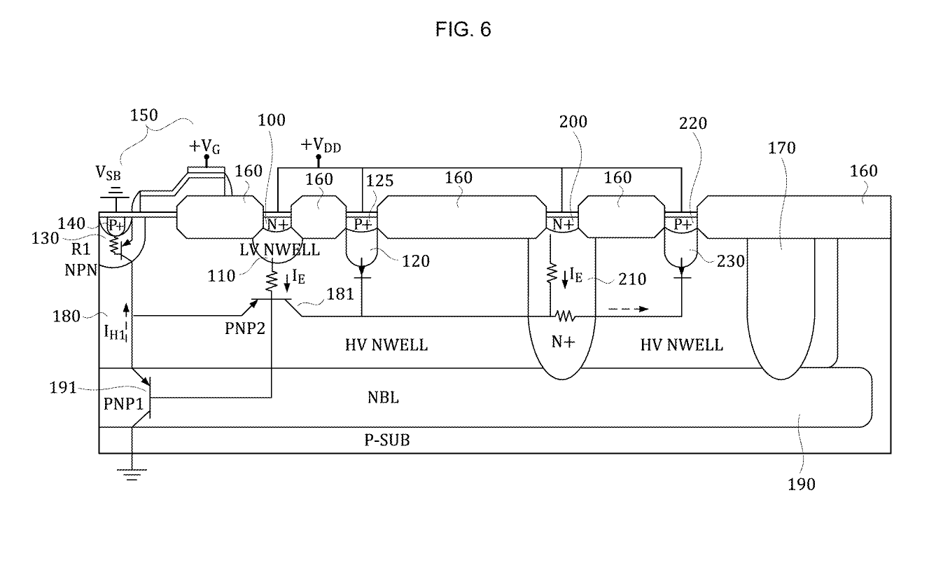

FIG. 6 is a cross-sectional view illustrating operation of the exemplary LDMOS device of FIG. 5.

Referring to FIG. 6, the hole current of the parasitic bipolar transistor (e.g., PNP1) 191 flows to the deep n-type sink region (n+ sink) 210. In addition, the deep n-type sink region (n+ sink) 210 forms a parallel resistance structure together with the LV NWELL 110 and drain region 100, thus reducing the resistance of the drift region.

As such, the decrease in the resistance causes neither deterioration in on-state break down voltage (Bvii) nor promotion of operation of the parasitic PNP1 191, thus advantageously reducing current gain (Hfe) of the parasitic PNP1 191.

In certain embodiments, the LDMOS may be a 20 to 85 volt-grade LDMOS.

As will be apparent from the foregoing description, a deep n+-type ion-implanted region is provided outward from the drain region, thereby reducing current gain (Hfe) of a parasitic PNP junction and thus decreasing hole current (noise-causing factor) flowing to the semiconductor substrate.

In addition, although a PWELL as a guardring is provided, deterioration in on-state break down voltage (Bvii) can be prevented. As a result, safe operating area (SOA) properties can be improved.

It will be apparent to those skilled in the art that various modifications and variations can be made in the present invention without departing from the spirit or scope of the invention. Thus, it is intended that the present invention covers the modifications and variations provided they come within the scope of the appended claims and their equivalents.

What is claimed is:

1. A lateral double diffused metal oxide semiconductor (LDMOS) device, comprising:
a semiconductor substrate comprising a buried region and a first well region;
a gate on the semiconductor substrate;
a body region in the first well region and a source region in the body region on one side of the gate;
a drift region and a drain region in the drift region on an opposite side of the gate relative to the body region;
a second well region, a deep first sink region and a third well region in the first well region; and
a deep second sink region in the first well region.

2. The LDMOS device according to claim 1, further comprising a device isolation film isolating the drift region, the drain region, the second well region, the first deep sink region, the third well region, and the second deep sink region from one another.

3. The LDMOS device according to claim 1, wherein the drain region, the second well region, the first deep sink region, and the third well region are electrically connected.

4. The LDMOS device according to claim 1, wherein the first well region comprises a high voltage n-well.

5. The LDMOS device according to claim 1, wherein the drift region comprises a low voltage n-well.

6. The LDMOS device according to claim 1, wherein the second and third well regions comprise p-type wells.

7. The LDMOS device according to claim 1, wherein the first and second deep sink regions comprise heavily doped n-type sink regions.

8. The LDMOS device according to claim 1, wherein the first deep sink region completely penetrates the buried region.

9. The LDMOS device according to claim 1, further comprising a first contact region in the second well region.

10. The LDMOS device according to claim 9, further comprising a second contact region in the deep first sink region.

11. The LDMOS device according to claim 10, wherein the first contact region comprises a heavily-doped p-type contact region, and the second contact region comprises a heavily-doped n-type contact region.

12. A method of making a lateral double diffused metal oxide semiconductor (LDMOS) device, comprising:
forming a buried region and a first well region in a semiconductor substrate;
forming first and second deep sink regions in the first well region, where the first deep sink region is in electrical contact with the buried region;
forming a device isolation layer on and/or in the semiconductor substrate;
forming a gate on the semiconductor substrate and at least part of the device isolation layer;
forming a low voltage well in the first well region on one side of the gate;
forming a body region, a second well region and a third well region in the first well region, where the body region is on an opposite side of the gate relative to the low voltage well;
forming a source region in the body region and first and second contact regions in the second and third well regions; and
forming a drain region in the low voltage well region and a third contact region in the first deep sink region.

13. The method of claim 12, further comprising forming a conductive layer on the semiconductor substrate electrically connecting the drain region, the second well region, the first deep sink region, and the third well region.

14. The method of claim 12, wherein forming the first and second deep sink regions comprises implanting n-type impurities in the first well region.

15. The method of claim 12, wherein forming the body region, the second well region and the third well region comprises implanting p-type impurities in the first well region.

16. The method of claim 12, wherein forming the source region and the first and second contact regions comprises implanting a high concentration of p-type impurities.

17. The method of claim 12, wherein forming the drain region and the third contact region comprises implanting a high concentration of n-type impurities.
